(19) United States
(12) Patent Application Publication
(10) Pub. No.: US 2019/0051593 A1
(43) Pub. Date: Feb. 14, 2019

(54) DISPLAY DEVICE

(71) Applicant: Japan Display Inc., Tokyo (JP)

(72) Inventors: Hiroyuki Kimura, Tokyo (JP); Yasuhito Aruga, Tokyo (JP); Hideaki Abe, Tokyo (JP); Hitoshi Kawaguchi, Tokyo (JP)

(21) Appl. No.: 16/058,405

(22) Filed: Aug. 8, 2018

(30) Foreign Application Priority Data
Aug. 10, 2017 (JP) 2017-155963

(51) Int. Cl. H01L 23/498; H01L 27/12; H01L 27/32; G02F 1/1368; G02F 1/1362; H01L 23/00; G02F 1/1333; G02F 1/1345

(52) U.S. Cl. CPC H01L 23/49838; G02F 2001/13685; H01L 27/3276; G02F 1/1368; G02F 1/136286; H01L 24/06; H01L 24/32; H01L 23/4985; H01L 27/323; G02F 1/13338; G02F 1/13452; G02F 1/13458; H01L 2224/06151; H01L 2224/06155; H01L 2224/32145; H01L 27/124

(57) ABSTRACT

According to one embodiment, a display device includes a first signal wiring disposed on an insulating substrate, a base substrate, a first connection wiring on the base substrate and a conductive adhesive member which electrically connects the first signal wiring and the first connection wiring, wherein the base substrate includes a first end surface overlapping the first signal wiring, the insulating substrate includes a second end surface overlapping the first connection wiring, the first connection wiring has a first width in a position overlapping the first end surface and a second width in a position overlapping the second end surface, and the first width is less than the second width.

### CROSS-REFERENCE TO RELATED APPLICATIONS

This application is based upon and claims the benefit of priority from Japanese Patent Application No. 2017-155963, filed Aug. 10, 2017, the entire contents of which are incorporated herein by reference.

### FIELD

Embodiments described herein relate generally to a display device.

### BACKGROUND

Conventionally, flexible wiring substrates formed from a flexible base material of polyimide or the like are used to connect an element substrate on which display elements and detection elements are disposed and a control substrate on which drive IC chips for driving the display elements and the detection elements are and a CPU for controlling the drive IC chips, and the like are disposed, to each other. Examples of the method of arranging the drive IC chips in display devices or detection devices are a chip-on-glass (COG) mode, which arranges drive IC chips on an element substrate on which display elements and detection elements are disposed, and a chip-on-film (COF), which arranges drive IC chips on a wiring substrate. As compared to the COG mode, it is not possible with the COF mode to reduce the number of wirings on a wiring substrate using drive IC chips, resulting in increasing of the number of the connection wirings on the wiring substrate.

In recent years, especially, in display devices comprising high-definition pixels or in fingerprint detecting devices comprising high-definition detection elements arranged therein, the number of display elements or detection elements is increasing, and accordingly, the number of wirings on the element substrate or the wiring substrate is increasing. As a result, the intervals between connection wirings of the wiring substrate are narrowed, possibly causing misconnection between wirings in a manufacturing process or the like.

### BRIEF DESCRIPTION OF THE DRAWINGS

FIG. 1 is a diagram showing a configuration of a display device of this embodiment.

FIG. 2 is a cross-sectional view of the display device taken along line A-B shown in FIG. 1.

FIG. 3 is a plan view of the display device shown in FIG. 2 between lines C and D.

FIG. 4 is another plan view of the display device shown in FIG. 2 between lines C and D.

FIG. 5 is a diagram showing a processing step of forming a wiring substrate.

FIG. 6 is a diagram showing a basic configuration and an equivalent circuit, of a display panel.

FIG. 7 is a cross-sectional view showing a partial configuration of the display panel shown in FIG. 1.

FIG. 8 is a cross-sectional view showing another partial configuration example of the display panel shown in FIG. 1.

FIG. 9 is a plan view of a modification of the wiring substrate of this embodiment.

FIG. 10 is a plan view of another modification of the wiring substrate of this embodiment.

FIG. 11 is a plan view of still another modification of the wiring substrate of this embodiment.

FIG. 12 is a diagram showing a configuration of a detection device.

FIG. 13 is a cross-sectional view of the detection device taken along line E-F shown in FIG. 12.

FIG. 14 is a plan view showing a sensor of the detection device shown in FIG. 12.

FIG. 15 is a cross-sectional view of the detection device taken along line G-H shown in FIG. 14.

FIG. 16 is a plan view showing another example of the sensor of the detection device shown in FIG. 12.

FIG. 17 is a cross-sectional view of the detection device taken along line I-J shown in FIG. 14.

### DETAILED DESCRIPTION

In general, according to one embodiment, a display device comprises an insulating substrate, a first signal wiring disposed on the insulating substrate, a base substrate, a first connection wiring disposed on the base substrate and a conductive adhesive member which electrically connects the first signal wiring and the first connection wiring to each other, wherein the base substrate includes a first end surface overlapping the first signal wiring, the insulating substrate includes a second end surface overlapping the first connection wiring, the first connection wiring has a first width in a position overlapping the first end surface and a second width in a position overlapping the second end surface, and the first width is less than the second width.

According to one embodiment, a display device comprises an insulating substrate, a first signal wiring and a second signal wiring disposed on the insulating substrate, a base substrate, a first connection wiring and a second connection wiring disposed on the base substrate and a conductive adhesive member which electrically connects the first signal wiring and the second signal wiring to the first connection wiring and the second connection wiring, respectively, wherein the base substrate comprises a first end surface overlapping the first signal wiring and the second signal wiring, the insulating substrate comprises a second end surface overlapping the first connection wiring and the second connection wiring, a first distance between the first connection wiring and the second connection wiring in a position overlapping the first end surface is greater than a second distance between the first connection wiring and the second connection wiring in a position overlapping the second end surface.

According to one embodiment, a display device comprises an insulating substrate, a first signal wiring disposed on the insulating substrate, a base substrate, a first connection wiring disposed on the base substrate and a conductive adhesive member which electrically connects the first signal wiring and the first connection wiring to each other, wherein the base substrate comprises a first end surface overlapping the first signal wiring, and the first end surface has a wavy shape in plan view.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

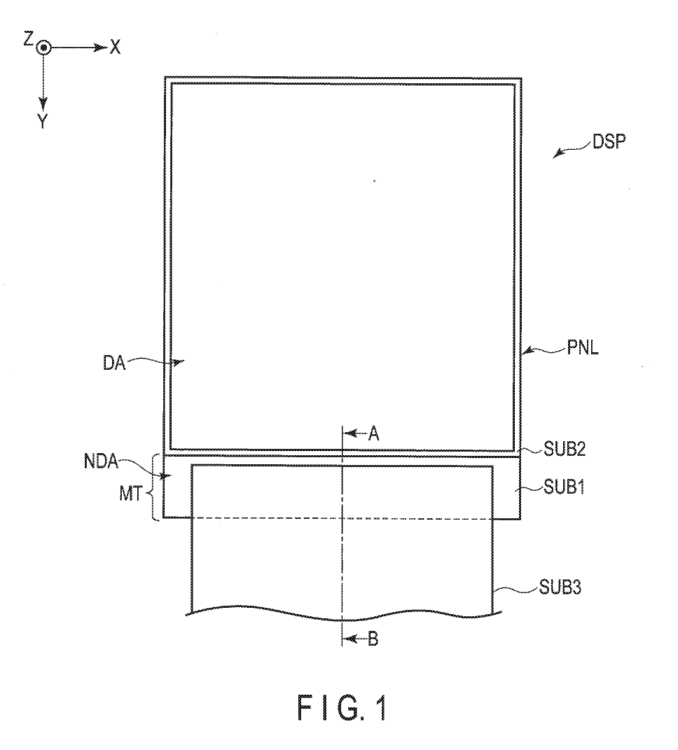

FIG. 1 is a diagram showing a configuration of a display device DSP of an embodiment.

In the drawing, a first direction X, a second direction Y, and a third direction Z orthogonally cross each other, but they may cross each other at any angle other than 90 degrees. The first direction X and the second direction Y correspond to a direction parallel to a main surface of the substrate which constitutes the display device DSP, and the third direction Z corresponds to a thickness direction of the display device DSP.

In the following description, a direction towards a tip of an arrow indicating the third direction Z is referred to as “up”, and a direction backwards from the tip of the arrow is referred to as “down”. Such expressions as “a second member above a first member” and “a second member below a first member” are meant the second member may be in contact with or spaced from the first member. Further, a view of an X-Y plane defined by the first direction X and the second direction Y from the tip side of the arrow indicating the third direction Z is defined as plan view.

The display device DSP comprises a display panel PNL including a first substrate SUB1 and a second substrate SUB2, and a wiring substrate SUB3. The first substrate SUB1 and the second substrate SUB2 oppose each other along the third direction Z. The display panel PNL includes a display area DA for displaying images and a frame-like non-display area NDA surrounding the display area DA.

The wiring substrate SUB3 is electrically connected to the display panel PNL. The first substrate SUB1 includes a mounting portion MT on an outer side of a region which overlaps the second substrate SUB2, and the wiring substrate SUB3 is mounted on the mounting portion MT. In the example illustrated, the width of the wiring substrate SUB3 along the first direction X is less than the width of the display panel PNL along the first direction X.

The wiring substrate SUB3 is, for example, a flexible substrate. To applicable to this embodiment, it suffices if the flexible substrate at least partially includes a flexible portion formed from a bendable material. The wiring substrate SUB3 of this embodiment may be, for example, a flexible substrate which is entirely flexible, or may be a rigid flexible substrate including a rigid portion formed of a rigid material such as glass epoxy and a flexible portion formed of a bendable material such as polyimide.

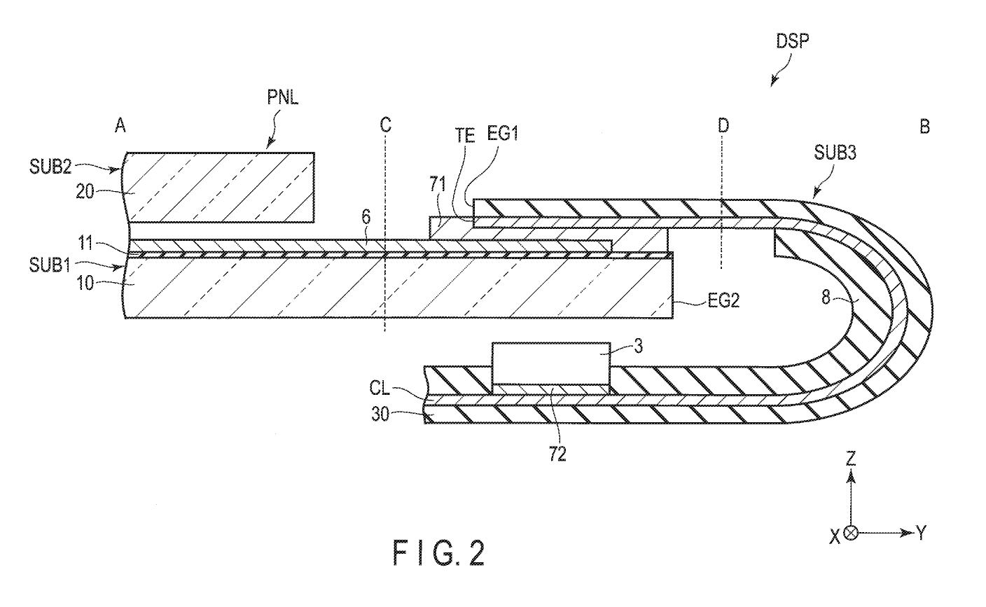

FIG. 2 is a cross-sectional view of the display device DSP taken along line A-B shown in FIG. 1.

The display device DSP comprises, in addition to the display panel PNL and the wiring substrate SUB3, a drive IC chip 3 and conductive adhesives 71 and 72. Note that FIG. 2 illustrates only the main structure of this embodiment and detailed illustration is omitted.

The first substrate SUB1 comprises at least a first insulating substrate 10, an insulating film 11 and signal wirings 6. The first insulating substrate 10 is, for example, a glass substrate or a resin substrate. The insulating film 11 is disposed on the first insulating substrate 10. The signal wirings 6 are disposed on the first insulating substrate 10 via the insulating film 11. The second substrate SUB2 comprises at least a second insulating substrate 20. The second substrate SUB2 is, for example, a glass substrate or a resin substrate. Note that the display panel PNL comprises a liquid crystal layer, light-emitting elements and the like as display functional layers between the first insulating substrate 10 and the second insulating substrate 20.

The wiring substrate SUB3 comprises a base substrate 30, connection wirings CL and an insulating film 8. The connection wirings CL are disposed on the base substrate 30. The connection wirings CL are formed from copper foil, for example. Further, the connection wirings CL may be plated with a material which cannot be easily oxidized, for example, gold. The insulating film 8 covers the connection wirings CL. The wiring substrate SUB3 is bent so as to be located below the first insulating substrate 10.

The conductive adhesive 71 is in contact with the signal wirings 6 and the connection wirings CL. The signal wirings 6 are electrically connected to the connection wirings CL, respectively by the electrically conductive adhesive 71. That is, the display panel PNL and the wiring substrate SUB3 are electrically connected and also attached to each other via the conductive adhesive 71.

The conductive adhesive 71 contains conductive particles dispersed therein. Therefore, when the display panel PNL and the wiring substrate SUB3 are pressurized from upper and lower sides along the third direction Z while interposing the conductive adhesive 71 therebetween, they are connected electrically and physically to each other.

The drive IC chip 3 is disposed on the wiring substrate SUB3. That is, the drive IC chip 3 is electrically connected to the connection wirings CL attached to the base substrate 30 with the conductive adhesive 72.

The base substrate 30 includes an end surface (first end surface) EG1. The end surface EG1 overlaps the signal wirings 6 along the third direction Z. The first insulating substrate 10 includes an end surface (second end surface) EG2. The end surface EG2 overlaps the connection wirings CL along the third direction Z. The connection wirings CL each include an end surface TE in a position overlapping the end surface EG1 along the third direction Z. The end surfaces TE are covered by the conductive adhesive 71.

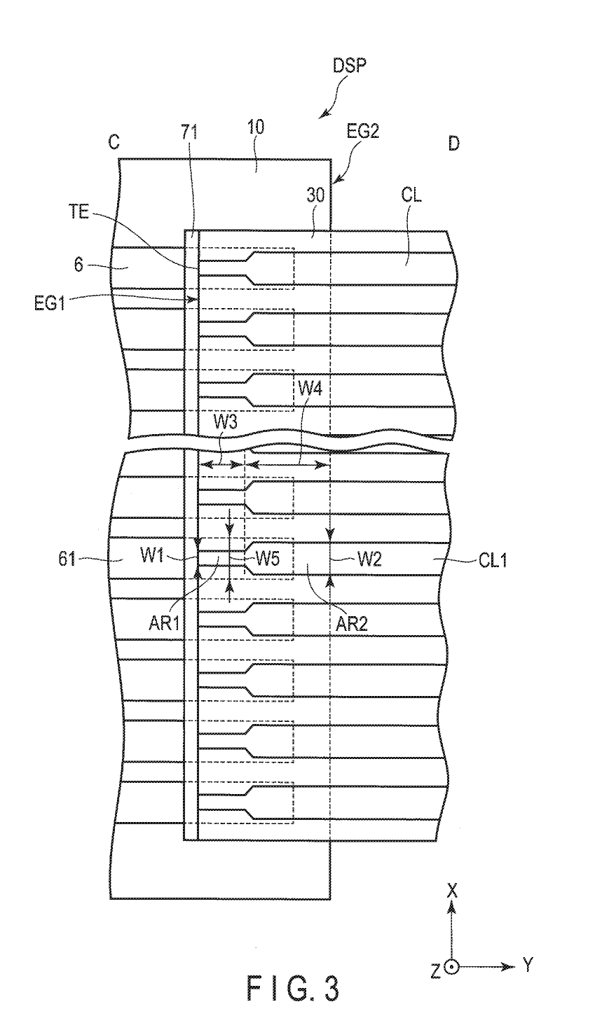

FIG. 3 is a plan view of the display device DSP shown in FIG. 2 between lines C and D.

A plurality of connection wirings CL are disposed on the base substrate 30 and arranged side by side along the first direction X with intervals therebetween, each extending along the second direction Y. Here, the structure of the connection wirings CL of this embodiment will be described by focusing on a first connection wiring CL1. The first connection wiring CL1 extends along the second direction Y and comprises a first area AR1 including one end surface TE along the second direction Y and a second area AR2 adjacent to the first area AR1. The first connection wiring CL1 has a first width W1 in the first area AR1 along the first direction X and a second width W2 in the second area AR2 along the first direction X. In this embodiment, the wiring has the first width W1 in a position overlapping the end surface EG1 of the base substrate 30 included in the first area AR1, and the second width W2 in a position overlapping the end surface EG2 of the first insulating substrate 10 included in the second area AR2. In this embodiment, the first width W1 is less than the second width W2. For example, a third width W3 of the first area AR1 taken from the end surface EG1 of the base substrate 30 along the second direction Y is 20 to 80 μm. Further, a fourth width W4 of the second area AR2 taken from the end surface EG2 of the first insulating substrate 10 along the second direction Y is 500 to 700 μm. In other words, the first area AR1 and the second area AR2 correspond to a region where the end surface EG1 of the base substrate 30 of the first connection wiring CL1 and the first insulating substrate 10 overlap each other, and a ratio W3/W4 between the first area AR1 and the second area AR2 is 0.04 to 0.11. Here, the width W1 is 4 to 12 μm, and the second width is 10 to 15 μm. That is, a ratio W1/W2 between the first width W1 and the second width W2 is 0.4 to 0.8. A ratio of the second width W2 to the first width W1 is more than 1 to 3.75.

A plurality of signal wirings 6 are disposed on the first insulating substrate 10 and arranged side by side along the first direction X with intervals therebetween, each extending along the second direction Y. The signal wirings 6 each overlap the connection wiring CL1 between the end surfaces EG1 and EG2 in plan view. For example, the first signal wiring 61 overlaps the first connection wiring CL1 in plan view. Further, the first signal wiring 61 is electrically connected to the first connection wiring CL1 by the conductive adhesive 71. Note that the first signal wiring 61 has a fifth width W5 between the end surfaces EG1 and EG2. In the example illustrate, the first width W1 is greater than the second width W2.

As shown in FIG. 2, the conductive adhesive 71 covers the end surface TE of each connection wiring CL. Thus, the conductive adhesive 71 is located on an outer side of the region which overlaps the base substrate 30. That is, the conductive adhesive 71 is exposed from the base substrate 30 along with the end surface EG1. Note that, the end surface EG2 doesn't overlap the first signal wiring 61, and the end surface EG2 doesn't overlap the end surface EG1 in plan view.

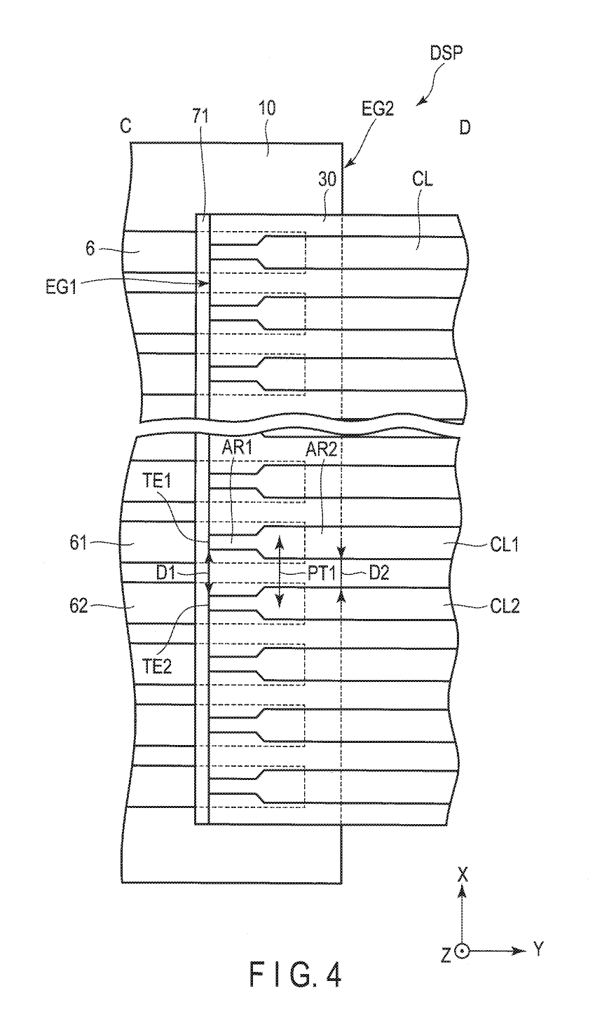

FIG. 4 is a plan view of the display device DSP shown in FIG. 2 between the lines C and D.

Second connection wirings CL2 are arranged side by side along the first direction X of the first connection wiring CL1. Further, the second signal wiring 62 is arranged next to the first signal wiring 61 in the first direction X. The second signal wiring 62 overlaps the second connection wiring CL2 in plan view. Further, the second signal wiring 62 is electrically connected to the second connection wiring CL2 by the conductive adhesive 71. An end surface TE1 of the first connection wiring CL1 and an end surface TE2 of the second connection wiring CL2 are each covered by the conductive adhesive 71.

In the position overlapping the end surface EG1 included in the first area AR1, the second connection wiring CL2 is spaced from the first connection wiring CL1 by a first distance D1. In the position overlapping the end surface EG2 included in the second area AR2, the second connection wiring CL2 is spaced from the first connection wiring CL1 by a second distance D2. In this embodiment, the first distance D1 is greater than the second distance D2. For example, the first distance D1 is 18 to 26 μm, and the second distance D2 is 15 to 20 μm. In other terms, a ratio D1/D2 between the first distance D1 and the second distance D2 is 1.2 to 1.3. Further, a ratio W1/D1 between the first distance D1 and the first width W1 is about 1.5 to 6.5, and a ratio W2/D1 between the second distance D2 and the second width W2 is about 1 to 2. A ratio of the first distance D1 to the second distance D2 is more than 1 to 1.73.

The first connection wiring CL1 and the second connection wiring CL2 are arranged side by side at a pitch PT1. Here, the pitch PT1 is equivalent to the distance between the center of the first connection wiring CL1 along the first direction X and the center of the second connection wiring CL2 along the first direction X. For example, when the drive IC chip is mounted on the first substrate SUB1 unlike this embodiment, the number of connection wirings CL will be about 300, and the pitch PT1 will be about 120 μm. On the other hand, when the drive IC chip is mounted on the wiring substrate as in this embodiment, the number of connection wirings CL is about 1,000 to 2,000, and the pitch PT1 is about 30 μm.

That is, as compared with the case where the drive IC chip is mounted on the first substrate SUB1, the number of connection wirings CL is greater and the pitch PT1 is less in this embodiment.

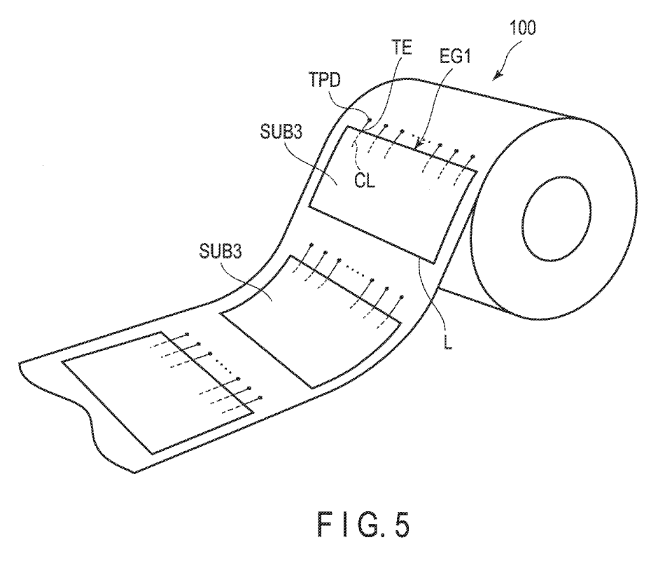

FIG. 5 illustrates the processing step of forming the wiring substrate SUB3.

A mother board 100 for forming wiring substrates SUB3 is wound around a reel. A plurality of wiring substrates SUB3 are formed by being cut out from the mother board 100 with a cutting die. The mother board 100 comprises a base substrate 30, connection wirings CL, and an insulating film 8 such as shown in FIG. 2. Test pads TPD to test the electrical connection of the wiring substrates SUB3 are arranged on an outer side of each wiring substrate SUB3. The connection wirings CL are drawn out to the outside of each wiring substrate SUB3 and are connected respectively to the test pads TPD. With this configuration, the end surfaces TE of the connection wiring CL are located on a cut line L. Note that each wiring substrate SUB3 may comprise, for example, two-layered electrode layer, but there is only one layer for the end surfaces TE of the connection wirings CL located on the cut line L.

As described above, the connection wirings CL are located on the cut line L; therefore burrs may be created in the connection wirings CL in a position which overlaps the end surface EG1, possibly causing short-circuiting between adjacent connection wirings CL. Further, because they are cut on the cut line L, the end surfaces TE of the connection wirings CL are not plated to expose the copper foil.

According to this embodiment, in the connection wirings CL, the first width W1 in the position which overlaps the end surface EG1 is less than the second width W2 in the position which overlaps the end surface EG2. Further, the first distance D1 between adjacent connection wirings in the end surface EG1 is greater than the second distance D2 between the respective connection wirings in the end surface EG2. That is, by narrowing the width of each connection wirings CL in the end surface EG1, the distance between each adjacent pair of connection wirings can be increased. Therefore, if a burry is created in the position which overlaps the end surface EG1, the occurrence of short-circuiting between connection wirings can be suppressed.

Moreover, according to this embodiment, the conductive adhesive 71 covers the end surfaces TE of the connection wirings CL. With this configuration, even if the copper foil is exposed in an end surface TE, corrosion of the connection wirings CL, which may occur from such an end surface TE, can be suppressed.

Therefore, a display device with improved reliability can be obtained.

A liquid crystal display panel will be explained here as a specific example of the display device PNL.

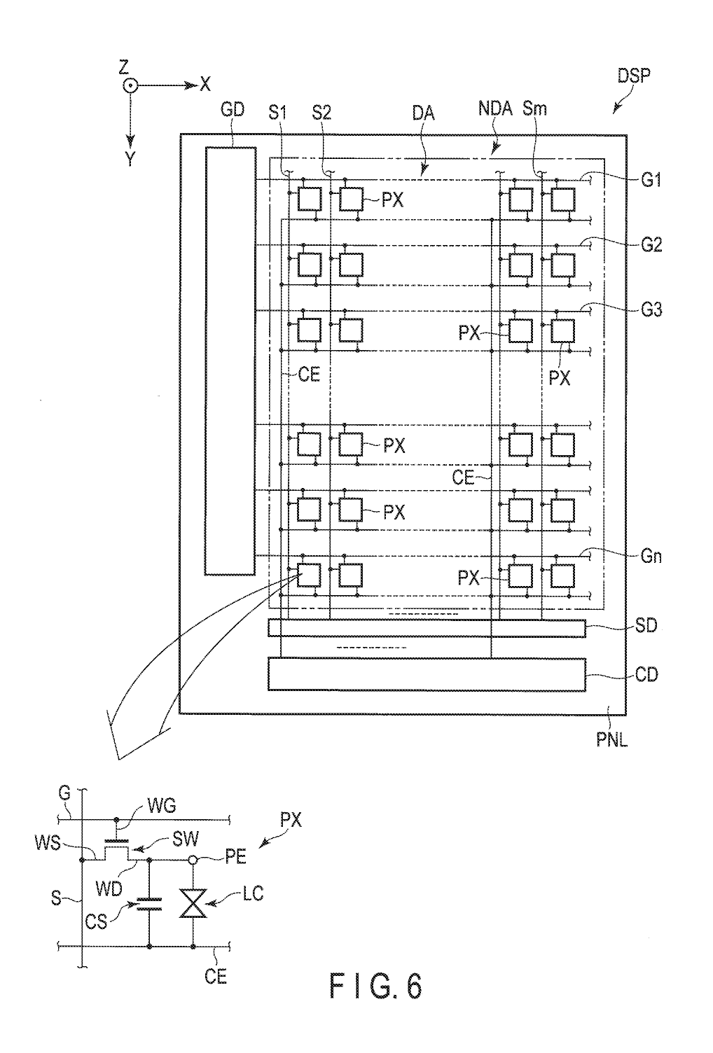

FIG. 6 is a diagram showing a basic configuration and an equivalent circuit, of the display panel PNL. The display panel PNL includes a plurality of pixels PX in the display area DA. Here, each pixel PX indicates a minimum unit individually controllable according to pixel signals, and it is located, for example, in a respective region which includes a switching element disposed at position where a scanning line and a respective signal line cross each other, which will be described later. The pixels PX are arrayed in a matrix along the first direction X and the second direction Y. Further, the display panel PNL comprises a plurality of scanning lines G (G1 to Gn), a plurality of signal lines S (S1 to Sm), a common electrode CE and the like in the display area DA. The scanning lines G each extend along the first direction X so as to be arranged along the second direction Y. Note that the signal lines S each extend along the second direction Y so as to be arranged along the first direction X. The scanning lines G and the signal lines S may not necessarily extend linearly, but may be partially bent. The common electrode CE is disposed over the pixels PX. The scanning lines G, the signal lines S and the common electrode CE are each drawn out to the non-display area NDA. In the non-display area NDA, the scanning lines G are connected to a scanning line drive circuit GD, the signal lines S are connected to a signal line drive circuit SD, and the common electrode CE is connected to a common electrode drive circuit CD. In this embodiment, the signal line drive circuit SD, the scanning line drive circuit GD and the common electrode drive circuit CD are disposed on the first substrate SUB1. At least one of the signal line drive circuit SD, the scanning line drive circuit GD and the common electrode drive circuit CDs may be built in the drive IC chip.

Each pixel PX comprises a switching element SW, a pixel electrode PE, the common electrode CE, a liquid crystal layer LC and the like. The switching element SW is constituted by a thin-film transistor (TFT), for example, and is electrically connected to a scanning line G and a signal line S. More specifically, the switching element SW includes a gate electrode WG, a source electrode WS, and a drain electrode WD. The gate electrode WG is electrically connected to the scanning line G. In the example illustrated, an electrode electrically connected to the signal line S is referred to as the source electrode WS, and an electrode electrically connected to the pixel electrode PE is referred to as the drain electrode WD.

The scanning lines G are connected to the switching elements SW of the respective pixels PX arranged along the first direction X. The signal lines S are connected to the switching elements SW of the respective pixels PX arranged along the second direction Y. Each pixel electrode PE opposes the common electrode CE, and drives the liquid crystal layer LC by an electric field produced between the pixel electrode PE and the common electrode CE. A storage capacitance CS is formed between, for example, the common electrode CE and the pixel electrode PE.

Moreover, the scanning line drive circuit GD supplies a scanning signal to select a pixel PX to drive to the scanning line G, and the signal line drive circuit SD supplies a pixel signal to the pixel PX select with the scanning signal via the signal line S and the switching element SW. The common electrode drive circuit CD supplies a drive signal to drive a pixel PX to the common electrode CE.

In this embodiment, peripheral circuits including the scanning line drive circuit GD, the signal line drive circuit SD and the common electrode drive circuit CD are connected with the drive IC chip on the wiring substrate SUBS via the signal wirings 6 and the connection wiring CL. From the drive IC chip, control signals for driving the display elements or peripheral circuits are supplied. The control signals include, for example, timing control signals for controlling the timing of the scanning line drive circuit GD, the signal line drive circuit SD or the common electrode drive circuit CD, scanning signals, pixel signals, drive signals and the like.

Note that at least one of the signal line drive circuit SD, the scanning line drive circuit GD and the common electrode drive circuit CDs may be built in the drive IC chip. In this case, the built-in peripheral circuit(s) to be connected is connected to the drive IC chip via the signal wirings 6 and the connection wirings CL. For example, when the common electrode drive circuit CD is built in, the common electrode CE and the drive IC are connected to each other via the signal wirings 6 and the connection wirings CL.

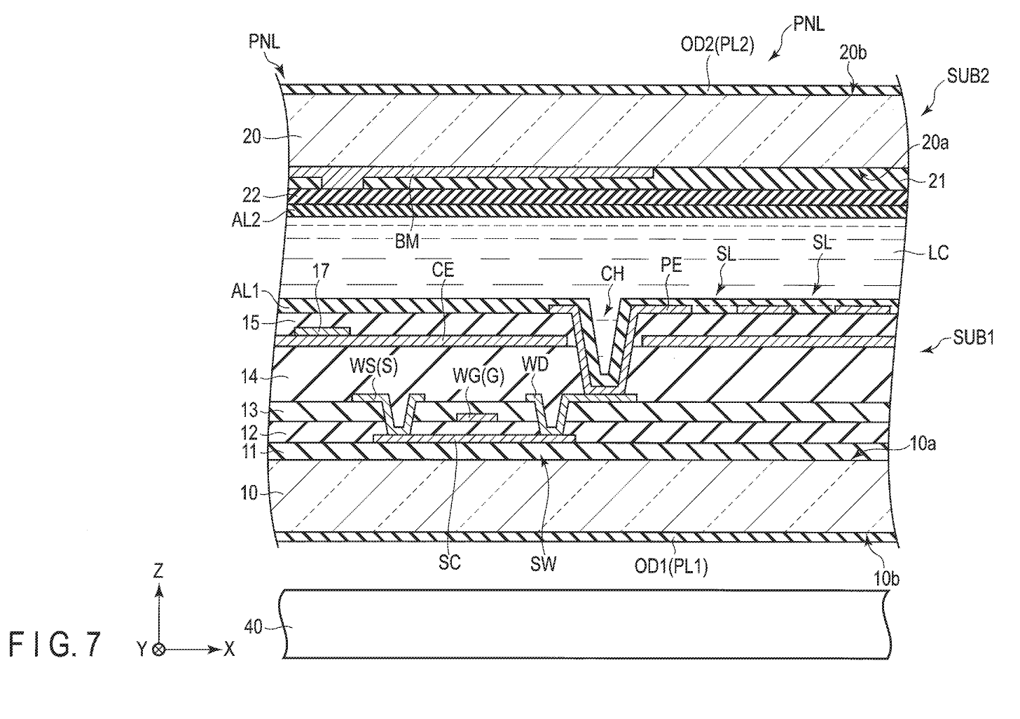

FIG. 7 is a cross-sectional view showing a partial configuration of the display panel PNL shown in FIG. 1.

Here, only the main portions necessary for explanation are shown. Note that the display panel PNL illustrated has a structure corresponding to the display mode which mainly utilizes a lateral electric field substantially parallel to the main surface of the substrate, but it is not particularly limited to this. The panel may have a structure corresponding to a display mode utilizing a vertical electric field perpendicular to the main surface of the substrate, or an electric field in an oblique direction, or a combining of these fields. In the display mode utilizing a lateral electric field, such a configuration is applicable, in which, for example, both side of the pixel electrodes PE and the common electrode CE are provided in either one of the first substrate SUB1 and the second substrate SUB2. In the display mode utilizing a vertical electric field or an oblique electric field, such a configuration is applicable, in which, for example, either one side of the pixel electrodes PE and the common electrode CE is provided in the first substrate SUB1, and the other side is provided in the second substrate SUB2. Note noted that the main substrate surface is a surface parallel to the X-Y plane.

The first substrate SUB1 comprises a first insulating substrate 10, a first insulating film 11, a switching element SW, a common electrode CE, a metal wiring 17, a pixel electrode PE, a first alignment film AL1 and the like.

The first insulating layer 11 is located on a main surface 10a of the first basement 10. The switching element SW is disposed on the first insulating film 11. The switching element SW comprises a semiconductor layer SC, a source electrode WS electrically connected to the respective signal line S, a gate electrode WG electrically connected to the respective scanning line G, a drain electrode WD and the like. The semiconductor layer SC is formed on the first insulating film 11. The semiconductor layer SC is formed of, for example, polysilicon. The second insulating film 12 covers the semiconductor layer SC. The gate electrode WG is formed on the second insulating film 12. The third insulating film 13 covers the gate electrode GE. The source electrode WS and the drain electrode WD are disposed on the third insulating film 13 and electrically connected to the semiconductor layer SC via a contact hole penetrating the second insulating film 12 and the third insulating film 13. The fourth insulating film 14 covers the switching element SW.

The common electrode CE is located between the fourth insulating film 14 and a fifth insulating film 15. The pixel electrode PE1 is located between the fifth insulating film 15 and the first alignment film AL1. The pixel electrode PE has a slit SL at a position opposing the common electrode CE. The pixel electrode PE is electrically connected to the switching element SW via a contact hole CH formed in the fourth insulating film 24 and the third insulating film 23. The common electrode CE and the pixel electrodes PE are formed of a transparent conductive material such as indium-tin-oxide (ITO) or indium-zinc-oxide (IZO). In order to lower the resistance of the common electrode CE, the metallic wiring 17 brought into contact with the common electrode CE may be provided.

As shown in FIG. 7, conductive layers which form the scanning lines G and the signal lines S via the third insulating film 13 are located between the first insulating substrate 10 and the fourth insulating film 14. These conductive layers are formed of, for example, a metal material such as Cu, Al or Mo. One of the conductive layers corresponds to the signal wirings 6. Further, these conductive layers each include a terminal portion formed to be partially exposed in the non-display area NDA, and these terminal portions are connected to the connection wirings CL on the wiring substrate SUBS via the conductive adhesive 71. In other words, in the non-display area NDA, the insulating films which cover over the conductive layers include an opening in a region, and the terminal portions are located in positions corresponding to the opening. Note that the terminal portion may be covered by a transparent conductive material such as ITO or IZO, which forms the pixel electrodes PE and the common electrode CE.

The pixel electrodes PE may be located between the fourth insulating film 14 and the third insulating film 15, and the common electrode CE may be located between the fifth insulating film 15 and the first alignment film AL1. In this case, the pixel electrodes PE are formed in a plate shape including no slit in each pixel, and the common electrode CE includes slits opposing the pixel electrodes PE. Both sides of the pixel electrodes PE and the common electrode CE may be arranged along the first direction X. For example, the pixel electrodes PE and the common electrode CE may be both formed in a comb-like shape and arranged so as to be engaged with each other. In such arrangement, for example, the fifth insulating film 15 illustrated here may be omitted and both sides of the pixel electrodes PE and the common electrode CE may be located between the fourth insulating film 14 and the first alignment film AL1.

The second substrate SUB2 comprises a second insulating substrate 20, a color filter layer 21, an overcoat layer 22, a second alignment film AL2, a light-shielding layer BM and the like. The color filter layer 21 and the light-shielding layer BM are disposed on a main surface 20a of the second insulating substrate 20. The overcoat layer 22 covers the color filter layer 21 and the light-shielding layer BM. The second alignment film AL2 covers the overcoat layer 20. The liquid crystal layer LC is located between the first substrate SUB1 and the second substrate SUB2.

A first optical element OD1 including a first polarizer PL1 is disposed on the main surface 10b of the first insulating substrate 10. In other words, the first optical element OD1 is located between the first insulating substrate 10 and an illumination device 40. A second optical element OD2 including a second polarizer PL2 is located on the main surface 20b of the second insulating substrate 20.

When the display device DSP is a liquid crystal display, the display panel PNL comprises a transmissive display function which displays images by selectively transmitting light from a rear surface side of the first substrate SUB1, but the configuration is not limited to this. For example, the display panel PNL may be of reflective type which selectively reflects light from a front surface side of the second substrate SUB2, or may comprise both the transmissive and reflective functions.

Next, an organic electroluminescent (EL) panel will be described as another example of the display panel PNL.

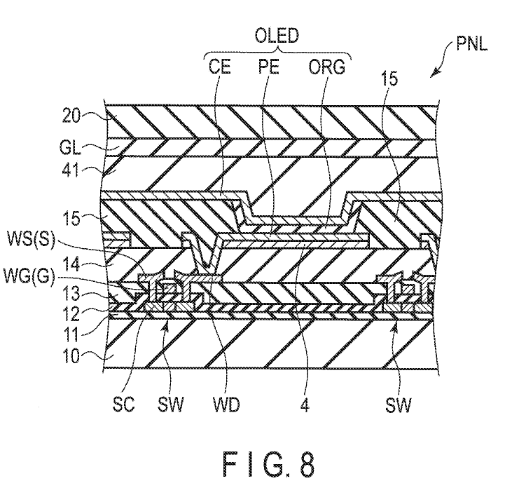

FIG. 8 is a cross-sectional view showing another configuration example of a part of the display panel PNL shown in FIG. 1. Here, only the main portions necessary for explanation are shown.

The display panel PNL comprises a first insulating substrate 10, a switching element SW, a reflective layer 4, an organic EL device OLED, a sealing layer 41, an adhesive member GL, a second insulating substrate 20 and the like. The first insulating substrate 10 is covered by the first insulating film 11. The switching element SW is formed on the first insulating film 11. The switching elements SW1 includes a semiconductor layer SC formed on the first insulating film 11. The semiconductor layer SC is covered by the second insulating film 12. The gate electrode WG of the switching element SW is formed on the second insulating film 12. The gate electrode WG is covered by the third insulating film 13.

The source electrode WS and the drain electrode WD of the switching element SW1 are formed on the third insulating film 13. The source electrode WS and the drain electrode WD are electrically connected to the semiconductor layer SC via the contact hole penetrating the second insulating film 12 and the third insulating film 13. The switching element SW1 is covered by the fourth insulating film 14. The reflective layer 4 is formed on the fourth insulating film 14. The reflective layer 4 is formed of a highly reflective metal material such as aluminum or silver. Note that an upper surface of the reflective layer 4 may be a flat surface, or an uneven surface to impart light scattering property.

The organic EL device OLED is formed on the fourth insulating film 14. In the example illustrated, the organic EL device OLED is electrically connected to the switching element SW. The organic EL device OLED is structured as a top-emission type which emits whit light toward the second substrate SUB2. In the illustrated example, the organic EL device OLED is partitioned by the fifth insulating film 15.

The organic EL device OLED comprises a pixel electrode PE formed on the reflective layer 4. The pixel electrode PE is electrically connected to the switching element SW.

For example, the organic EL device OLED comprises an organic light-emitting layer ORG which emits light in one of blue, red and green. The organic light-emitting layer ORG is located on the pixel electrode PE. Further, the organic EL device OLED includes the common electrode CE. The common electrode CE is located on the organic light-emitting layer ORG. The common electrode CE is located on the fifth insulating film 15 as well. One side of the pixel electrodes PE and the common electrode CE is a positive electrode and the other side is a negative electrode. The pixel electrodes PE and the common electrode CE are formed from, for example, a transparent conductive material such as ITO or IZO.

The sealing layer 41 covers over the organic EL device OLED. The sealing layer 41 seals the members disposed between the first insulating substrates 10 and itself. The sealing layer 41 inhibits the entering of oxygen or moisture to the organic EL device OLED, thus suppressing degradation of the organic EL device OLED. The sealing layer 41 may be formed from a multilayered body of an inorganic film and an organic layer.

The second insulating substrate 20 is located on the sealing layer 41 and adhered thereto using the adhesive member GL. The second insulating substrate 20 is equivalent to an optical film, which contains, for example, a polarizer and the like.

As in the case shown in FIG. 7, the conductive layers which form the scanning lines G and the signal lines S are located on the first insulating substrate 10. One of these conductive layers corresponds to the signal wirings 6.

Next, the variation in shape of the wiring substrate SUB3 will be described.

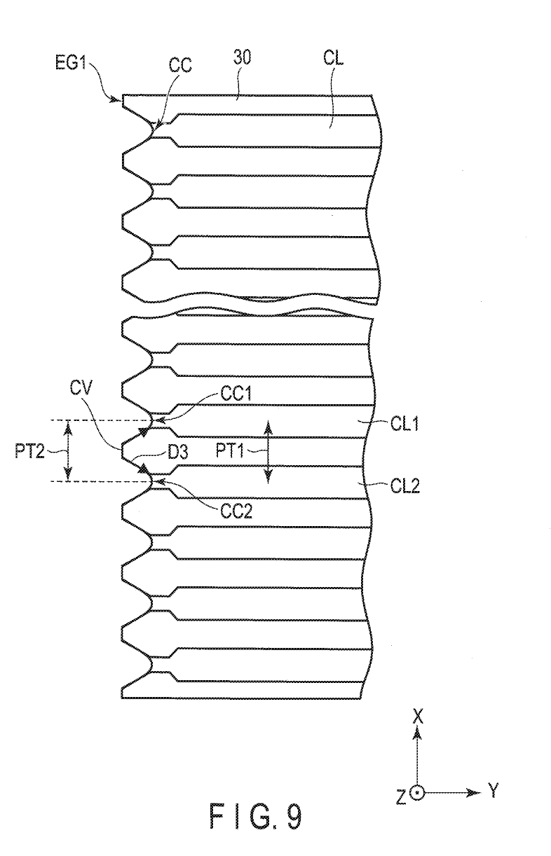

FIG. 9 is a plan view showing a modified example of the wiring substrate SUB3. The wiring substrate SUB3 shown in FIG. 9 is different from the wiring substrate SUB3 shown in FIG. 3 in that the end surface EG1 is formed into a wavy form in plan view.

The end surface EG1 has the wavy form which includes a first convexity CC1 and a second concavity CC2 in positions overlapping the first connection wiring CL1 and the second connection wiring CL2, respectively, and a convexity CV between the first connection wiring CL1 and the second connection wiring CL2. Here, the pitch of the wavy form of the end surface EG1 is defined as a pitch PT2. For example, the pitch PT2 corresponds to the distance between the center of the first concavity CC1 and the center of the second concavity CC 2 adjacent to the first concavity CC1. In the example illustrated, the pitches PT1 and PT2 are equal to each other. Further, in this embodiment, the pitches PT1 and PT2 are, for example, 20 to 40 μm.

As illustrated in FIG. 4, when the end surface EG1 is flat, a third distance D3 along the end surface EG1 between the first connection wiring CL1 and the second connection wiring CL2 is equal to the first distance D1 along the second direction between the first connection wiring CL1 and the second connection wiring CL2. On the other hand, as illustrated in FIG. 9, when the end surface EG1 is formed to be wavy, the third distance D3 along the end surface EG1 between the first connection wiring CL1 and the second connection wiring CL2 can be made greater than the first distance Dl. With this configuration, even if a burr is created in the connection wiring CL along the end surface EG1, short-circuiting between the first connection wiring CL1 and the second connection wiring CL2 can be suppressed. This is also the case for connection wirings CL adjacent to each other.

In the example shown in FIG. 9, the pitches PT1 and PT2 are equal to each other. Note that the pitches PT1 and PT2 may be different from each other. In this case as well, the third distance D3 between each connection wiring CL can be made to increase.

In such a modified example as described above, advantageous effects similar to those described above can be obtained.

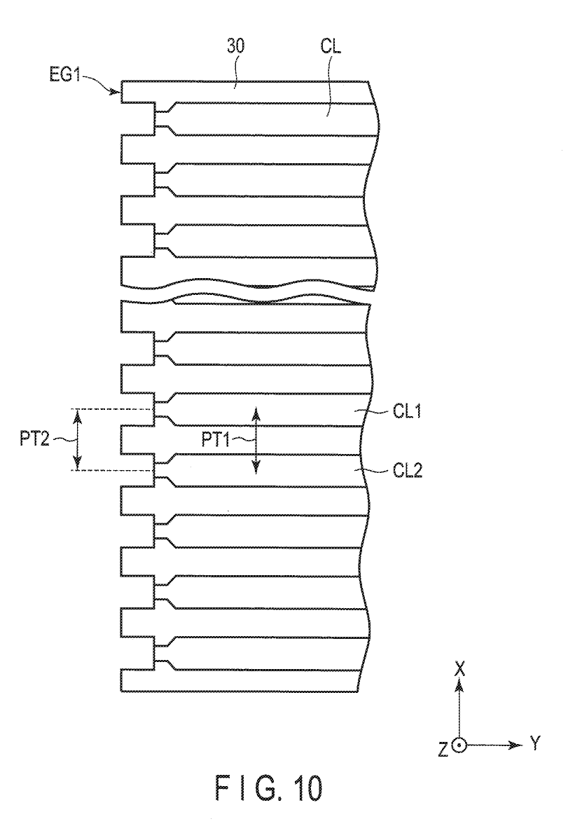

FIG. 10 is a diagram showing another modified example of the wiring substrate SUB3 of this embodiment. The wiring substrate SUB3 shown in FIG. 10 is different from the wiring substrate SUB3 shown in FIG. 9 in that the end portion EG1 is formed into a rectangular wave shape.

In the case where the end portion EG1 has a rectangular wavy wave, for example, the pitches PT1 and PT2 are equal to each other in the example shown in FIG. 9, but they may be different from each other.

FIGS. 9 and 10 each show the case where the end surface EG1 is formed into a wavy shape with a constant pitch PT2, but the shape of the end surface EG1 is not limited to this. The shape may be arbitrary as long as the third distance D3 along the end surface EG1 between the first connection wiring CL1 and the second connection wiring CL2 is greater than the first distance D1, which is the distance in straight line between the first connection wiring CL1 and the second connection wiring CL2 along the first direction.

In such a modified example as described above, advantageous effects similar to those described above can be obtained.

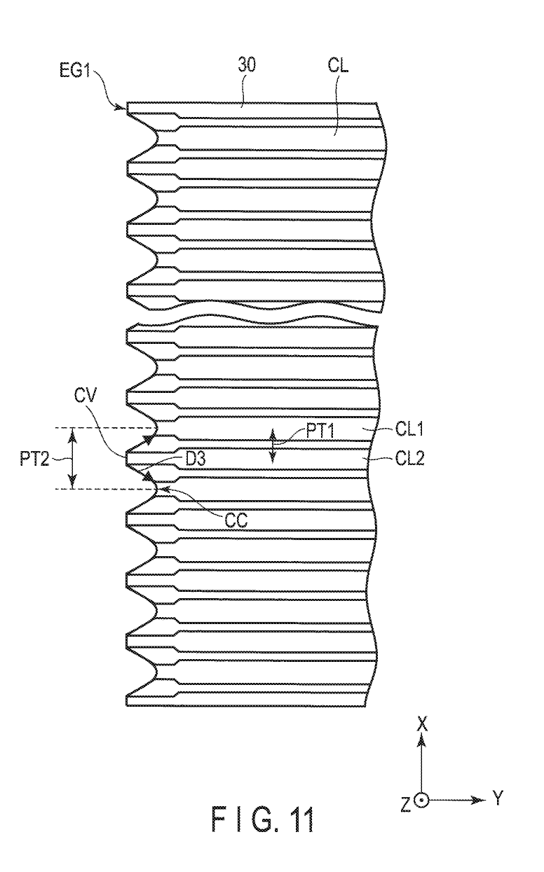

FIG. 11 is a diagram showing another modified example of the wiring substrate SUB3 of this embodiment. The wiring substrate SUB3 shown in FIG. 11 is different from the wiring substrate SUB3 shown in FIG. 9 in that the pitch PT2 of the end surface EG1 differs from the pitch PT1 between adjacent connection wirings CL.

When the pitches PT1 and PT2 differ from each other, for example, the end portion EG1 may be formed into a rectangular wave shape as shown in FIG. 10, or some other shape. Further, in this modified example, the pitch PT2 of the end surface EG1 is set to twice the pitch PT1 between adjacent connection wirings CL, but the configuration is not limited to this. The pitch PT2 of the end portion EG1 may be three times or more of the pitch PT1 between adjacent connection wirings CL, or there may be a plurality of pitches with different distances. The end surface EG1 has a concavity CC in the position overlapping the first connection wiring CL1 and a convexity CV in the position overlapping the second connection wiring CL2.

In such a modified example as described above, advantageous effects similar to those described above can be obtained.

The embodiment described above is explained in connection with an example case of the display device DSP in which display elements (pixels PX) are arranged on the first substrate SUB1, but the embodiment is not limited to that in which the elements are arranged on the first substrate SUB1. For example, the embodiment is applicable as well to a detection device DET in which detection elements are arranged on a first substrate.

An example case of the detection device DET will now be described.

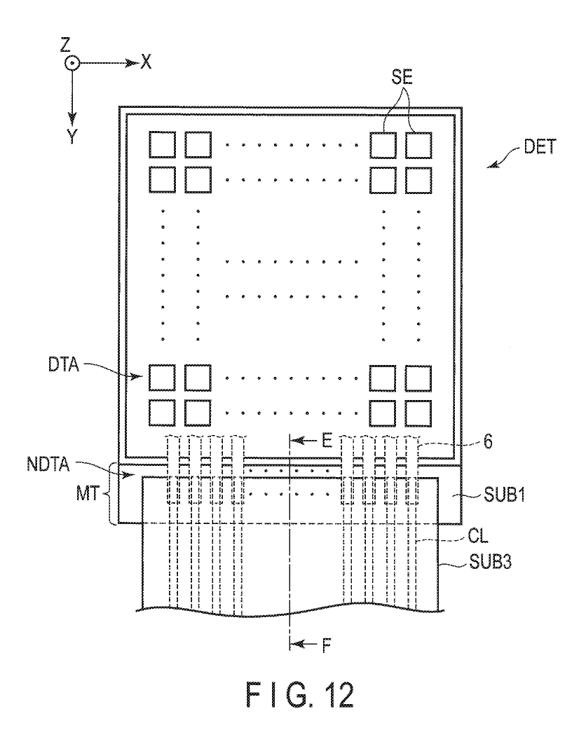

FIG. 12 is a diagram showing the structure of the detection device DET.

The detection device DET comprises a detection area DTA in which detection elements (sensors SE) are disposed, and a non-detection area NDTA on an outer side of the detection area DTA. Signal wirings 6 are connected to the detection element, respectively and drawn out to the non-detection area NDTA. A wiring substrate SUBS is connected to a first substrate SUB1 in a mounting portion MT. A plurality of connection wirings CL are connected respectively to the signal wirings 6 as in the above-described embodiment.

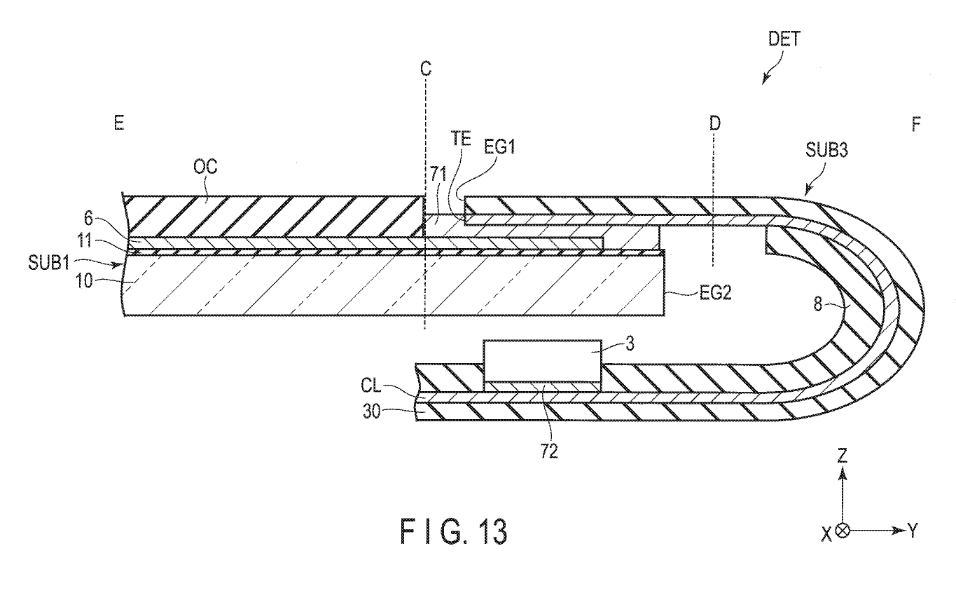

FIG. 13 is a cross-sectional view of the detection device shown in FIG. 12 taken along line E-F. The structure shown in FIG. 13 is different from that of the example shown in FIG. 2 in that the second substrate SUB2 is not provided and the overcoat layer OC is disposed on the first substrate SUB1.

The overcoat layer OC covers the signal wirings 6. Note that the plan view between the lines C and D is equivalent to those shown in FIGS. 3, 4, 9, 10 and 11.

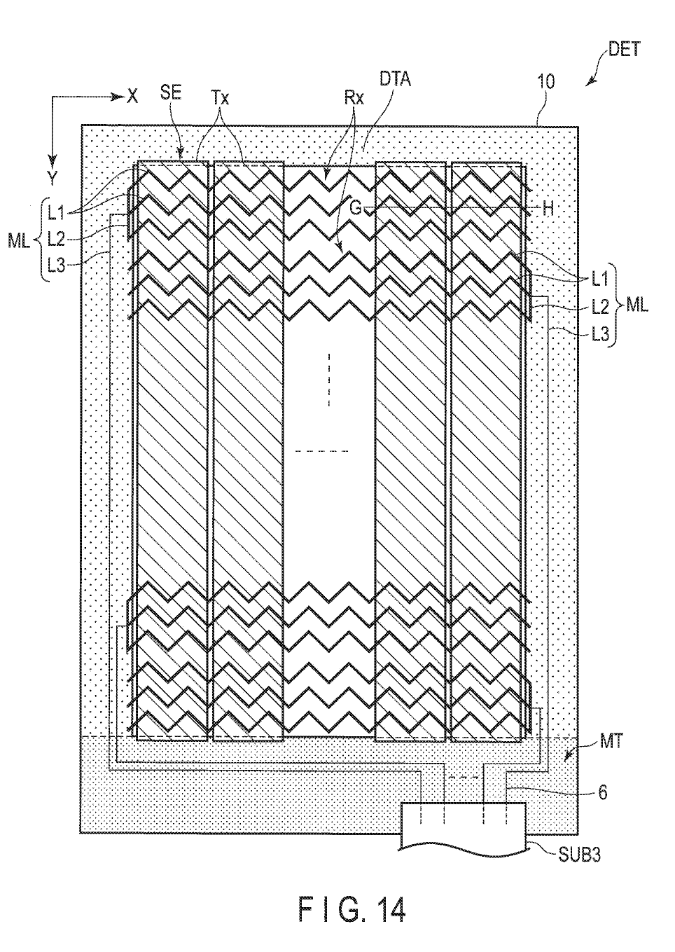

FIG. 14 is a plan view showing a sensor SE of the detection device shown in FIG. 12.

In the detection area DTA, drive electrodes Tx each extend along the second direction Y and are arranged along the first direction X at a constant pitch. The drive electrodes Tx are each formed into a rectangular shape, for example. In the detection area DTA, the detection electrodes Rx each extend along the first direction X and are arranged along the second direction Y at a constant pitch. Note that the embodiment is not limited to the example illustrated, but the drive electrodes Tx may extend along the first direction X and be arranged along the second direction Y at a constant pitch, whereas the detection electrodes Rx may extend along the second direction Y, and be arranged along the first direction X at a constant pitch. Each detection electrode Rx includes a plurality of detection lines L1 and a connection line LN2 connecting the detection lines LN1. The detection lines L1 connected by the connection line LN each extend zigzag in the first direction X drawing a wave form (specifically, a triangular wave form) and arranged along the second direction Y at a constant pitch. Note that the structure of the detection electrodes Rx is not limited to that of the example shown in FIG. 14. For example, the detection electrodes Rx may be formed of metal lines crossed in a mesh-like manner. The detection electrodes Rx and the drive electrodes Tx are each formed as a film on the first insulating substrate 10 from a transparent conductive material such as ITO. The detection electrodes Rx and the drive electrodes Tx may be each formed of a metal.

In the example of FIG. 14, counting from the top, odd-numbered detection electrodes Rx include connection lines L2 on the left-hand side of the detection area DTA, and a lead line L3 which connects these contact lines L2 and the wiring substrate SUBS extends along the left-hand side of the detection area DTA in the non-detection area NDTA. On the other hand, counting from the top, even-numbered detection electrodes Rx include connection lines L2 on the right-hand side of the detection area DTA, and a lead line L3 which connects these connection lines L2 and the wiring substrate SUBS extends along the right-hand side of the detection area DTA in the non-detection area NDTA. The lead lines L3 and the signal wirings 6 may be of the same material. Or, the lead lines L3 and the signal wirings 6 may be formed separately, in which case, the lead lines L3 and the signal wirings 6 are electrically connected respectively to each other.

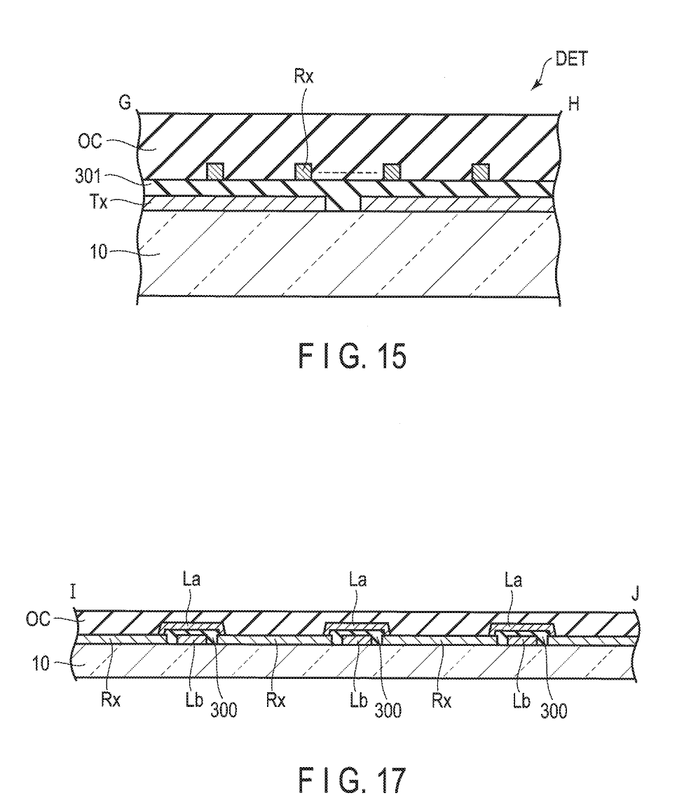

FIG. 15 is a cross-sectional view of the detection device DET shown in FIG. 14 taken along line G-H.

The detection device DET comprises a first insulating substrate 10, drive electrodes Tx, an insulating film 301, detection electrodes Rx and an overcoat layer OC. The drive electrodes TX are formed on the first insulating layer 10. The insulating film 301 covers the drive electrodes TX. The detection electrodes Rx are disposed on the insulating film 301. The overcoat layer OC covers the detection electrodes Rx.

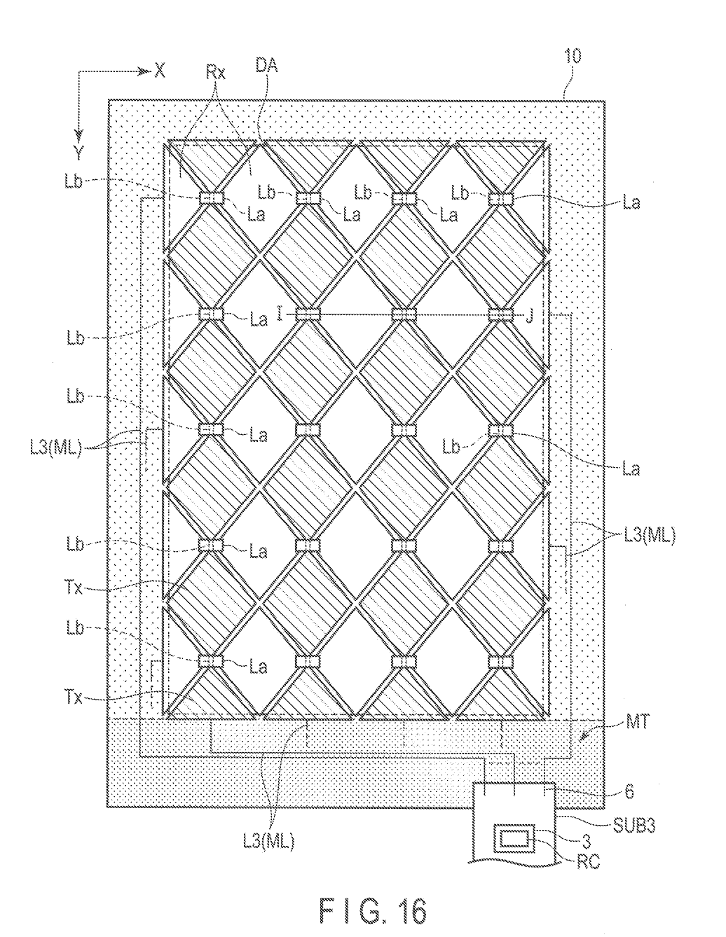

FIG. 16 is a plan view showing another example of a sensor SE of the detection device shown in FIG. 12.

The sensor SE includes a plurality of detection electrodes Rx and a plurality of drive electrodes Tx which supply detection signals to the detection electrodes Rx. In the detection area DTA, the detection electrodes Rx are arranged along the first direction X and the second direction Y. In the detection area DTA, the drive electrodes Tx are arranged along the first direction X and the second direction Y to be spaced from the respective detection electrodes Rx with gaps. The detection electrodes Rx and the drive electrodes Tx each have a rhombic shape diagonals of which are along the first direction X and the second direction Y, respectively. The detection electrodes Rx and the drive electrodes Tx are formed as films on the first insulating substrate 10 from a transparent conductive material such as ITO. Note that the detection electrodes Rx and the drive electrodes Tx may be each formed of a metal. Each pair of detection electrodes Rx adjacent to each other along the first direction X are electrically connected to each other with a first connection line La. Each pair of drive electrodes Tx adjacent to each other along the second direction Y are electrically connected to each other with a second connection line Lb.

In the example of FIG. 16, of a plurality of detection electrodes Rx arranged along the second direction Y on the left-hand side of the detection area DTA, lead lines L3 are connected to odd-numbered detection electrodes Rx counting from the top of the figure. These lead lines L3 extend along the second direction Y in the non-detection area NDTA on the left-hand side of the detection area DTA, and are connected to the wiring substrate SUB3 in the mounting portion MT via the signal wiring 6. On the other hand, of a plurality of detection electrodes Rx arranged along the second direction Y on the right-hand side of the detection area DTA, lead lines L3 are connected to even-numbered detection electrodes Rx counting from the top of the figure. These lead lines L3 extend along the second direction Y in the non-detection area NDTA on the right-hand side of the detection area DTA, and are connected to the wiring substrate SUB3 in the mounting portion MT via the signal wiring 6.

In this embodiment, the lead lines L3 are formed of a metal material such as aluminum (Al), molybdenum (Mo) or an alloy containing one of these. The lead lines L3 are an example of the metal layer ML. When the lead lines L3 are formed of a metal material, the resistance of the lead lines L3 can be kept low as compared to the case where the lead lines L3 are formed of a transparent conductive material such as ITO. Therefore, the time constant of the sensor SE can be improved. Note that the lead lines L3 and the signal wirings 6 may be formed of the same material.

On the other hand, the lead lines L3 are connected to the drive electrodes Tx arranged along the first direction X near the mounting portion MT. These lead lines L3 are connected to the wiring substrate SUB3 via the signal wiring 6 in the mounting portion MT. To the drive electrodes Tx, sensor drive signals are supplied from the wiring substrate SUB3. A detection circuit RC is provided to acquire sensor output signals from the detection electrodes Rx in synchronous with the supply of the sensor drive signals and detect, based on the sensor output signals, an object brought into contact with or approaching the detection area DTA. The detection circuit RC can also detect the position of the object brought into contact with or approaching it. Note that the detection circuit RC is built in the drive IC chip 3 disposed on the wiring substrate SUB3.

FIG. 17 is a cross-sectional view of the detection device DET shown in FIG. 4 taken along line I-J. The detection electrodes Rx and the second connection lines Lb are disposed on the first insulating substrate 10. The second connection lines Lb are arranged between the adjacent detection electrodes Rx so as to be spaced from the respective detection electrodes Rx with gaps. The second connection lines Lb are covered by the insulating film 300.

The first connection lines La is disposed on the insulating film 300 and in contact with adjacent detection electrodes Rx. The first connection lines La are called, for example, bridges. The first connection lines La and the second connection lines Lb are formed from, for example, a transparent conductive material such as ITO. The overcoat layer OC covers the detection electrodes Rx and the first connection lines La.

The signal wirings 6 shown in FIG. 12 may be formed from the same material as that for the conductive layer which forms the detection electrodes Rx or the drive electrodes Tx. Or, the signal wirings 6 may be a metal layer different from which the material used to form the detection electrodes Rx or the drive electrodes Tx. For example, in the non-detection area NDTA, peripheral circuits such as a detection drive circuit which supplies sensor drive signals to the drive electrode Tx and a selection circuit which selectively outputs sensor output signals from the detection electrodes Rx may be formed on the first insulating substrate 10. When these peripheral circuits are formed, the switching element SW may be provided between the drive electrodes Tx and the first insulating substrate 10 via an insulating layer. When the switching element SW is disposed on the first insulating substrate 10, the signal wirings 6 may be formed from a conductive layer which forms the gate electrode WG, the source electrode WS or the drain electrode WD as in the display device DSP.

FIGS. 14 and 16 illustrate a sensor SE of the sensing system which uses detection electrodes Rx and drive electrodes Tx, (which is called, for example, a mutual capacitance detection system). However, the sensor SE may be of some other sensor system such as a system which uses, for example, the capacitance of the detection electrode itself, (which is called, for example, a self-capacitance detection system). The self-capacitance detection system may be configured to carry out touch detection with either one of the detection electrode Rx and the drive electrode Tx, omitting the other. The detection device DET may comprises, as a detection element (sensor SE), an optical sensor or an ultrasonic sensor.

According the configuration of this embodiment described above, the number of connection wirings CL on the wiring substrate SUBS can be increased, and therefore it is applicable especially to a detection device which requires high definition detectability, such as a fingerprint detecting device.

As described above, according to the embodiments, a display device with improved reliability can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an insulating substrate;
a first signal wiring disposed on the insulating substrate;
a base substrate;
a first connection wiring disposed on the base substrate; and
a conductive adhesive member which electrically connects the first signal wiring and the first connection wiring to each other, wherein
the base substrate comprises a first end surface overlapping the first signal wiring,
the insulating substrate comprises a second end surface overlapping the first connection wiring,
the first connection wiring has a first width in a position overlapping the first end surface and a second width in a position overlapping the second end surface, and
the first width being less than the second width.

2. The display device of claim 1, wherein
the first connection wiring is covered by the conductive adhesive member in the position overlapping the first end surface.

3. The display device of claim 1, wherein
the first end surface has a wavy shape in plan view.

4. The display device of claim 1, further comprising an IC chip disposed on the base substrate and electrically connected to the first connection wiring.

5. The display device of claim 1, wherein
the first width is 4 to 12 μm and the second width is 10 to 15 μm.

6. The display device of claim 1, wherein
a ratio of the second width to the first width is more than 1 to 3.75.

7. The display device of claim 1, wherein
the second end surface doesn't overlap the first signal wiring.

8. The display device of claim 1, wherein
the second end surface doesn't overlap the first end surface in plan view.

9. A display device comprising:
an insulating substrate;
a first signal wiring and a second signal wiring disposed on the insulating substrate;
a base substrate;
a first connection wiring and a second connection wiring disposed on the base substrate; and
a conductive adhesive member which electrically connects the first signal wiring and the second signal wiring to the first connection wiring and the second connection wiring, respectively, wherein
the base substrate comprises a first end surface overlapping the first signal wiring and the second signal wiring,
the insulating substrate comprises a second end surface overlapping the first connection wiring and the second connection wiring,
a first distance between the first connection wiring and the second connection wiring in a position overlapping the first end surface is greater than a second distance between the first connection wiring and the second connection wiring in a position overlapping the second end surface.

10. The display device of claim 9, wherein
the first connection wiring and the second connection wiring are covered by the conductive adhesive member in the position overlapping the first end surface.

11. The display device of claim 9, wherein
the first end surface has a wavy shape in plan view.

12. The display device of claim 11, wherein
a pitch between centers of the first connection wiring and the second connection wiring is equal to a pitch of the wavy shape of the first end surface.

13. The display device of claim 9, wherein
the pitch between centers of the first connection wiring and the second connection wiring is 20 to 40 μm.

14. The display device of claim 9, wherein
the first distance is 18 to 26 μm and the second distance is 15 to 20 μm.

15. The display device of claim 9, wherein
a ratio of the first distance to the second distance is more than 1 to 1.73.

16. The display device of claim 9, wherein
the first end surface has a concavity in the position overlapping at least one of the first connection wiring and the second connection wiring and a convexity between the first connection wiring and the second connection wiring.

17. The display device of claim 9, wherein
the first end surface has a concavity in the position overlapping the first connection wiring and a convexity in the position overlapping the second connection wiring.

18. A display device comprising:
an insulating substrate;
a first signal wiring disposed on the insulating substrate;
a base substrate;
a first connection wiring disposed on the base substrate; and
a conductive adhesive member which electrically connects the first signal wiring and the first connection wiring to each other, wherein
the base substrate comprises a first end surface overlapping the first signal wiring, and
the first end surface has a wavy shape in plan view.

19. The display device of claim 18, wherein
the first end surface has a wavy shape having a pitch of 20 to 40 μm.
